(19) United States
(12) Patent Application Publication
(10) Pub. No.: US 2024/0237270 A1
(43) Pub. Date: Jul. 11, 2024

(54) FLUID DEVICE

(71) Applicant: FIVEGRAND INTERNATIONAL CO., LTD., New Taipei City (TW)

(72) Inventor: TING-JUI WANG, New Taipei City (TW)

(21) Appl. No.: 18/389,825

(22) Filed: Dec. 20, 2023

(30) Foreign Application Priority Data
Jan. 9, 2023 (TW) 112100838

(51) Int. Cl. H05K 7/20; H02K 7/18

(52) U.S. Cl. CPC H05K 7/20145; H02K 7/1823; H05K 7/20272

(57) ABSTRACT

The present disclosure provides a fluid device including an assembly portion and a block portion. The assembly portion is for assembling with an object. The block portion is disposed at the assembly portion, and is for blocking or guiding a fluid. Thus, the fluid device of the present disclosure can provide a secure configuration and an effect of efficiently guiding or disturbing a fluid for heat dissipation.

### CROSS-REFERENCE TO RELATED APPLICATION

This non-provisional application claims priority under 35 U.S.C. § 119(a) on Patent Application No(s). 112100838 filed in Taiwan, R.O.C. on Jan. 9, 2023, the entire contents of which are hereby incorporated by reference.

### BACKGROUND OF THE INVENTION

### 1. Field of the Invention

The present disclosure relates to a fluid device, and in particular to a fluid device having a secure configuration and providing an effect of efficiently guiding or disturbing a fluid for heat dissipation.

### 2. Description of the Related Art

Heat is usually generated during the operation of an electronic apparatus, and thus a gas cooling or liquid cooling apparatus needs to be provided to meet heat dissipation requirements.

However, limited by an internal space of an electronic apparatus, it is frequent that a gas or a liquid may not be effectively guided for heat dissipation, resulting in degraded heat dissipation efficiency.

### BRIEF SUMMARY OF THE INVENTION

According to at least one embodiment of the present disclosure, a fluid device is provided by the present disclosure to achieve objects of having a secure configuration and providing an effect of efficiently guiding or disturbing a fluid for heat dissipation.

To achieve the above and other objects, a fluid device provided by the present disclosure includes a block portion for blocking or guiding a fluid. The fluid device further comprises an electric conductive portion for conducting electric power generated by a motion of the fluid device to power another conductive object, or for storing the electric power in a power storage or a battery.

A fluid device further provided by the present disclosure includes a block portion and a shaft. The block portion is for blocking or guiding a fluid. The shaft is combined with the block portion. The fluid device further includes an electric conductive portion for conducting electric power generated by a motion of the fluid device to power another conductive object, or for storing the electric power in a power storage or a battery.

A fluid device further provided by the present disclosure includes an assembly portion and a block portion. The assembly portion is for assembling with an object. The block portion is disposed at the assembly portion and is for blocking or guiding a fluid. The fluid device further includes an electric conductive portion for conducting electric power generated by a motion of the fluid device to power another conductive object, or for storing the electric power in a power storage or a battery.

A fluid device further provided by the present disclosure includes an assembly portion, a block portion and a shaft. The assembly portion is for assembling with an object. The block portion is for blocking or guiding a fluid. The shaft is combined with the block portion. The fluid device further includes an electric conductive portion for conducting electric power generated by a motion of the fluid device to power another conductive object, or for storing the electric power in a power storage or a battery.

Optionally, the assembly portion or one end or both ends of the shaft of the fluid device are provided with a stop portion, which stops against the block portion or the assembly portion.

Optionally, the assembly portion or the shaft is provided with a stop portion, the block portion is provided with a corresponding stop portion, and the stop portion and the corresponding stop portion are correspondingly stopped.

Optionally, the shaft is provided with a stop portion, the assembly portion is provided with a corresponding stop portion, and the stop portion and the corresponding stop portion are correspondingly stopped.

Optionally, the assembly portion is provided with a stop portion, the object is provided with a corresponding stop portion, and the stop portion and the corresponding stop portion are correspondingly stopped.

Optionally, the block portion is provided with a stop portion, the assembly portion is provided with a corresponding stop portion, and the stop portion and the corresponding stop portion are correspondingly stopped.

Optionally, the fluid device is picked up by a tool, the fluid device is moved by the tool to a default height of an assembly position of an object, and the fluid device is released or loosened from the tool, for the assembly portion to be placed at the assembly position of the object.

Optionally, the fluid device is picked up by a tool, the fluid device is moved by the tool to a default height of an assembly position of an object, the fluid device is pressed downward by the tool, and the fluid device is released or loosened from the tool, for the assembly portion to be placed at the assembly position of the object.

Optionally, the fluid device is picked up by a tool, the fluid device is moved by the tool to an assembly position of an object, the fluid device is elastically pressed downward by the tool, and the fluid device is released or loosened from the tool, for the assembly portion to be placed at the assembly position of the object.

Optionally, the fluid device is picked up by a tool, the fluid device is moved by the tool to an assembly position of the object, and the fluid device is released or loosened from the tool, for the assembly portion to be placed at the assembly position of the object.

Optionally, the fluid device is picked up by a tool, the fluid device is moved by the tool to an assembly position of the object, a contact of the fluid device with the object is sensed by the tool, and the fluid device is released or loosened from the tool, for the assembly portion to be placed at the assembly position of the object.

Optionally, after the fluid device is picked up by the tool, a comparison device is provided to compare the fluid device with an assembly position or an assembly distance of the object, and the fluid device is moved by the tool according to comparison information of the comparison device.

Optionally, the tool is a vacuum suction device, a fastener, a magnetic device, a fixture or a mechanical arm.

Optionally, the assembly portion has a weldable surface, a predetermined tin layer is provided between the object and the assembly portion, and the weldable surface and the tin layer are heated, cooled and solidified so as to combine the object with the assembly portion.

Optionally, the object is a printed circuit board including a copper layer, which is located below a tin layer so as to be heated and bonded with each other for welding.

Optionally, the assembly portion includes an engaging portion, and the engaging portion and a corresponding engaging portion are engaged so as to clamp the object.

Optionally, the assembly portion has a material storage space for pressing the object, for a material of the object to flow into or enter the material storage space.

Optionally, the assembly portion includes an expansion connection structure, which is pressed so as to be expansion connected to the object.

Optionally, the block portion includes a fastening portion, and more than one block portion is fastened with another via the fastening portion so as to increase an area of the block portion.

Optionally, the object includes a fluid, and the block portion performs blocking or rotates to change a direction of the fluid.

Optionally, the block portion is shaped as a sheet, a fan or a blade, and the block portion is movable or rotatable, or the block portion is at a fixed position.

Optionally, the block portion and the shaft are movable or rotatable, or the block portion and the shaft are fixed.

Optionally, the object includes an inlet portion, which is for a fluid to enter the object, for the fluid device to come into contact with the fluid.

Optionally, the object is provided with a chip, a CPU, a GPU or a heat generating assembly, and the block portion is disposed according to the position of the chip, the CPU, the GPU or the heat generating assembly to guide a fluid for heat dissipation.

Optionally, the object is a printed circuit board, a water cooling apparatus,

a gas cooling apparatus, a rack, a casing, a tray, a cage, a cupboard, a slide rail or a cabinet.

Optionally, the block portion is shaped as a fan or a blade, for driving the fluid to move, rotate or turn.

Optionally, the block portion is shaped as a sheet, a fan or a blade, and is for being installed at a local position of the object and for generating guidance for a fluid at the installation position or near the installation position for heat dissipation.

Optionally, the block portion is shaped as a sheet, a fan or a blade, and is for being installed at a position through which a fluid passes, and for generating guidance for the fluid at the installation position or near the installation position for heat dissipation.

Optionally, the fluid is a gas or a liquid.

Optionally, a tin solder is provided between the stop portion and the corresponding stop portion, wherein the tin solder is heated, cooled and solidified.

Optionally, the fluid device further includes an electric conductive portion, which is for conducting a current for powering and driving the block portion to operate.

Optionally, the electric conductive portion includes a positive electrode and a negative electrode, the object is a printed circuit, the object includes a corresponding electric conductive portion, and the positive electrode and the negative electrode are connected to the corresponding electric conductive portion.

Optionally, a hood is further provided to cover, shield or protect the block portion.

Optionally, the electric conductive portion includes a positive electrode and a negative electrode, the object includes a corresponding electric conductive portion, and the positive electrode and the negative electrode are connected to the corresponding electric conductive portion.

Optionally, the fluid device further include a heat conduction module connected to the block portion or a heat generator, and the heat conduction module is for conducting a heat source of the heat generator to the block portion for heat dissipation.

The heat conduction module includes a heat conductor or an intermediate heat conductor, the heat conductor is disposed at the heat generator, and the intermediate heat conductor is connected to the block portion or the heat conductor, or the heat conductor is for guiding a heat source of the heat generator to the intermediate heat conductor, or the intermediate heat conductor is for guiding the heat source to the block portion for heat dissipation.

Optionally, the fluid device, the assembly portion or the heat conduction module is welded or bonded to the object or a heat generator, for the fluid device, the assembly portion or the heat conduction module to be disposed at the body or the heat generator.

Optionally, a descending, sinking or downward force or a pull force is produced by heat welding performed so as to cool a tin solder from a liquid state to a solid state, or a descending, sinking or downward force or a pull force is produced by bonding, for the fluid device, the assembly portion or the heat conduction module to adhere with, lean against or become close to the object or the heat generator.

Optionally, the heat conduction module or a heat conductor of the heat conduction module includes a channel portion which is for a fluid to pass through for heat dissipation, or the channel portion is for a liquid fluid or a gaseous fluid to pass through for heat dissipation.

Optionally, the object is a printed circuit board, a water cooling apparatus, a gas cooling apparatus, a rack, a casing, a tray, a cage, a cupboard, a slide rail or a cabinet, or the heat generator is a chip, a CPU, a GPU or a heat generating assembly, or the fluid device is additionally provided with a hood that covers, shields or protects the block portion.

Optionally, the fluid device further includes a body, and the assembly portion is disposed at the body.

Optionally, the electric conductive portion guides electric power to a light emitter, a light emitting diode, a chip, a passive component, an active component, an optical component, a switch, a memory, a motor, a fan, a heat sink, a circuit board, a transistor, a power supply device, a wire, a circuit, a fastener, a lock, a handle, a battery, a power storage or a power generator.

### BRIEF DESCRIPTION OF THE DRAWINGS

To more clearly describe the technical solutions of the embodiments of the present disclosure and the prior art, accompanying drawings that need to be used as required in the embodiments are to be briefly introduced. It is obvious that the accompanying drawings below are merely some embodiments of the present disclosure, and other accompanying drawings can be obtained on the basis of the these accompanying drawings by a person of ordinary skill in the art without involving any inventive skill.

FIG. 1 is side schematic diagram of a fluid device according to a first embodiment of the present disclosure.

FIG. 2 is plan schematic diagram of a fluid device according to the first embodiment of the present disclosure.

FIG. 3 is a schematic diagram of a first assembly state of a fluid device of the present disclosure.

FIG. 4 is a schematic diagram of a second assembly state of a fluid device of the present disclosure.

FIG. 5 is a schematic diagram of a third assembly state of a fluid device of the present disclosure.

FIG. 6 is a schematic diagram of a fourth assembly state of a fluid device of the present disclosure.

FIG. 7 is a schematic diagram of a fifth assembly state of a fluid device of the present disclosure.

FIG. 8 is a schematic diagram of a sixth assembly state of a fluid device of the present disclosure.

FIG. 9 is a schematic diagram of a state of use of a fluid device according to a second embodiment of the present disclosure.

FIG. 10 is a schematic diagram of a state of use of a fluid device according to a third embodiment of the present disclosure.

FIG. 11 is a schematic diagram of a state of use of a fluid device according to a fourth embodiment of the present disclosure.

FIG. 12 is a schematic diagram of a state of use of a fluid device according to a fifth embodiment of the present disclosure.

FIG. 13 is a schematic diagram of a state of use of a fluid device according to a sixth embodiment of the present disclosure.

FIG. 14 is a schematic diagram of a state of use of a fluid device according to a seventh embodiment of the present disclosure.

FIG. 15 is a schematic diagram of a state of use of a fluid device according to an eighth embodiment of the present disclosure.

FIG. 16 is side schematic diagram of a fluid device according to a ninth embodiment of the present disclosure.

FIG. 17 is a first schematic diagram of a state of use of a fluid device

according to the ninth embodiment of the present disclosure.

FIG. 18 is a second schematic diagram of a state of use of a fluid device according to the ninth embodiment of the present disclosure.

FIG. 19 is a schematic diagram of a state of use of a fluid device according to a tenth embodiment of the present disclosure.

FIG. 20 is a schematic diagram of a state of use of a fluid device according to an eleventh embodiment of the present disclosure.

FIG. 21 is a schematic diagram of a state of use of a fluid device according to a twelfth embodiment of the present disclosure.

FIG. 22 is a schematic diagram of a state of use of a fluid device according to a thirteenth embodiment of the present disclosure.

FIG. 23 is a schematic diagram of a state of use of a fluid device according to a fourteenth embodiment of the present disclosure.

FIG. 24 is a schematic diagram of a state of use of a fluid device according to a fifteenth embodiment of the present disclosure.

### DETAILED DESCRIPTION OF THE INVENTION

A fluid device according to the embodiments of the present disclosure is further described with the accompanying drawings below.

The above and other technical details, features and effects of the disclosure are to become more readily apparent with the detailed description of the preferred embodiments given with reference to the drawings below. It should be noted that, the directional terms used in the embodiments below, for example, upper, lower, left, right, front and back are given merely with reference to the directions of the accompanying drawings. Thus, the directional terms are for illustration purposes and are not to be construed as limitations to the present disclosure. Moreover, in the embodiments below, the same or similar elements are represented by the same or similar denotations or numerals.

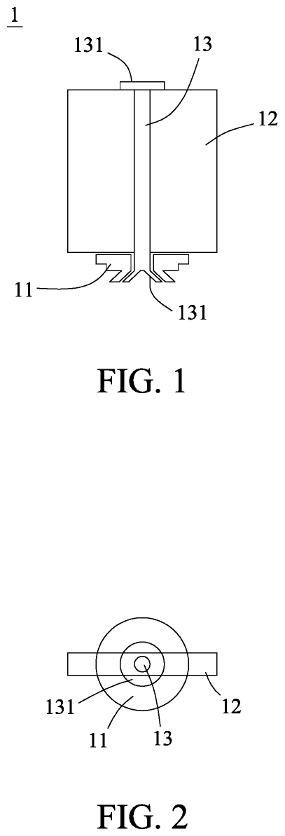

Refer to FIG. 1 and FIG. 2 showing a fluid device of the present disclosure. The fluid device 1 includes an assembly portion 11, a block portion 12 and a shaft 13.

The assembly portion 11 is for assembling with an object (not shown). The block portion 12 for blocking or guiding a fluid, which is a gas or a liquid.

The shaft 13 is combined with the block portion 12, or is combined with the assembly portion 11 and the block portion 12.

In practice, according to actual requirements, the assembly portion 11, the block portion 12 or the shaft 13 can be used with one another. For example, only the block portion 12 is provided, or the block portion 12 and the shaft 13 are provided, or the assembly portion 11 and the block portion 12 are provided, so as to meet actual application requirements.

During use, the fluid device 1 can be combined with the object by using the assembly portion 11, so that the fluid device 1 achieves an effect of being securely disposed at the object by using the assembly portion 11. Moreover, by using the shaft 13, the block portion 12 is configured to be a fixed type or a movable type, allowing a gas cooling apparatus on the object to produce a wind flow (or a liquid cooling apparatus to produce a liquid fluid), so as to guide a fluid to the block portion 12, for the block portion 12 to guide in a blocking manner or guide in a rotating manner to change a direction of the fluid. Thus, the fluid is guided to a position at which a heat source is produced or a position needing heat dissipation to use the fluid for heat dissipation, further enabling the block portion 12 to achieve an effect of efficiently guiding or disturbing the fluid for heat dissipation.

In one embodiment of the present disclosure, one end or both ends of the shaft 13 are provided with a stop portion 131, which stops against the block portion 12 or the assembly portion 11. In one embodiment of the present disclosure, each of both ends of the shaft 13 is provided with the stop portion 131, and each of the stop portions 131 stops against the block portion 12 and the assembly portion 11, so as to enable the block portion 12 and the assembly portion 11 to be securely assembled at the shaft 13.

In one embodiment of the present disclosure, the block portion 12 and the shaft 13 are movable or rotatable so that the block portion 12 is configured to be a movable type, or the block portion 12 and the shaft 13 are fixed in between so that the block portion 12 is configured to be a fixed type.

In one embodiment of the present disclosure, the object can be a printed circuit board, a water cooling apparatus, a gas cooling apparatus, a rack, a casing, a tray, a cage, a cupboard, a slide rail or a cabinet, thereby enabling the present disclosure to better meet actual application requirements.

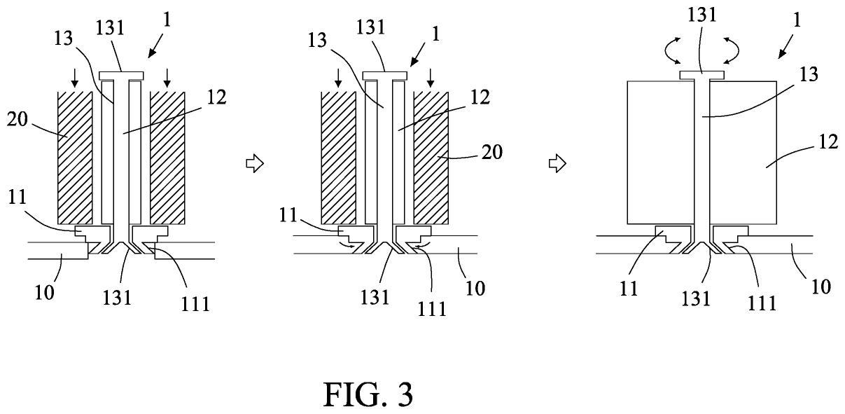

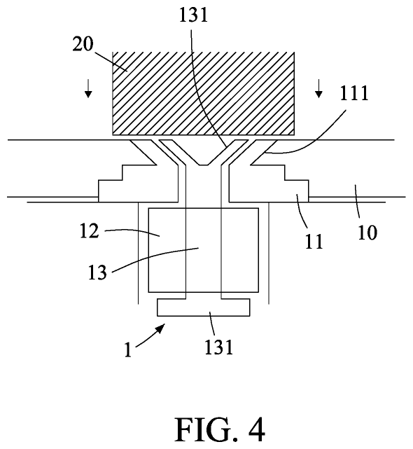

As shown in FIG. 3 and FIG. 4, in one embodiment of the present disclosure, a difference from the embodiment is that, the assembly portion 11 has a material storage space 111 for pressing the object 10, for a material of the object 10 to flow into or enter the material storage space 111 after the pressing. Thus, the assembly portion 11 can be stamped by a mold 20, such that the mold 20 presses the assembly portion 11 to cause the material of the object 10 to flow into or enter the material storage space 111 (as shown in FIG. 3), enabling the fluid device 1 to be securely combined with the object 10 by using the assembly portion 11. Moreover, the object 10 can also be stamped by a mold 20, such that the mold 20 presses the object 10 to cause the material of the object 10 to flow into or enter the material storage space 111 (as shown in FIG. 4), similarly enabling the fluid device 1 to be securely combined with the object 10 by using the assembly portion 11.

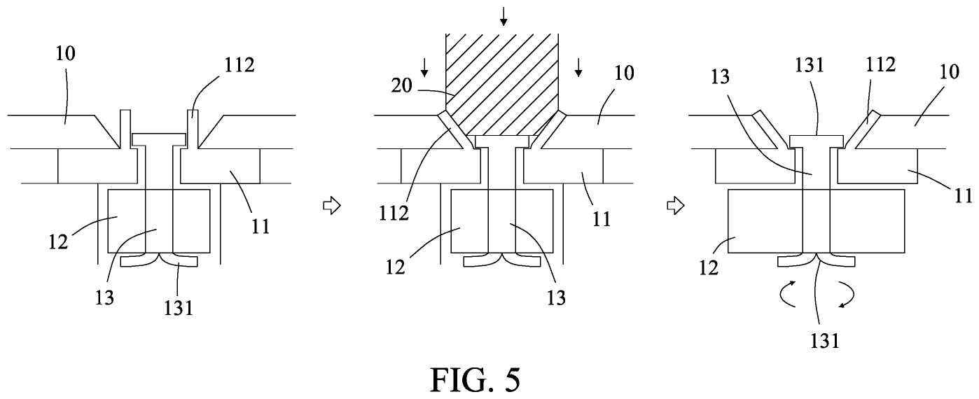

Referring to FIG. 5, in one embodiment of the present disclosure, a difference from the embodiments above is that, the assembly portion 11 includes an expansion connection structure 112. The expansion connection structure 112 is pressed, so as to be expansion connected to the object 10 when pressed. Thus, a force is applied on the expansion connection structure 112 of the assembly portion 11 by a mold 20, for the expansion connection structure 112 to be deformed and be expansion connected to the object 10 when pressed, enabling the fluid device 1 to be securely combined with the object 10 by using the assembly portion 11.

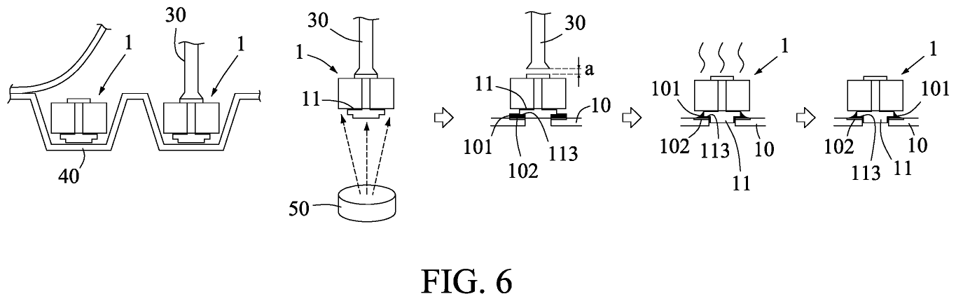

Referring to FIG. 6, in one embodiment of the present disclosure, a difference from the embodiments above is that, the fluid device 1 can be picked up from a carrier 40 by a tool 30, the fluid device 1 is moved by the tool 30 to a default height a of an assembly position of the object 10, and the fluid device 1 is released or loosened from the tool 30, for the assembly portion 11 to be placed at the assembly position of the object 10.

In one embodiment of the present disclosure, the fluid device 1 can also be directly moved by the tool 30 to an assembly position of the object 10, and the fluid device 1 is released or loosened from the tool 30, for the assembly portion 11 to be placed at the assembly position of the object 10.

In one embodiment of the present disclosure, after the fluid device 1 is picked up by the tool 30, a comparison device 50 is provided to compare the fluid device 1 with an assembly position or an assembly distance of the object 10, and the fluid device 1 is moved by the tool 30 according to comparison information of the comparison device 50, thereby enabling the present disclosure to better meet actual assembly requirements.

In one embodiment of the present disclosure, the tool 30 can be a vacuum suction device, a fastener, a magnetic device, a fixture of a mechanical arm, thereby enabling the present disclosure to better meet actual application requirements.

In one embodiment of the present disclosure, the assembly portion 11 has a weldable surface 113, a predetermined tin layer 101 is provided between the object 10 and the assembly portion 11, and the weldable surface 113 and the tin layer 101 are heated, cooled and solidified, allowing the fluid device 1 to be securely combined with the object 10 by using the assembly portion 11.

In one embodiment of the present disclosure, the object 10 is a printed circuit board including a copper layer 102, which is located below the tin layer 101 so as to be heated and bonded with each other for the use of welding with the weldable surface 113.

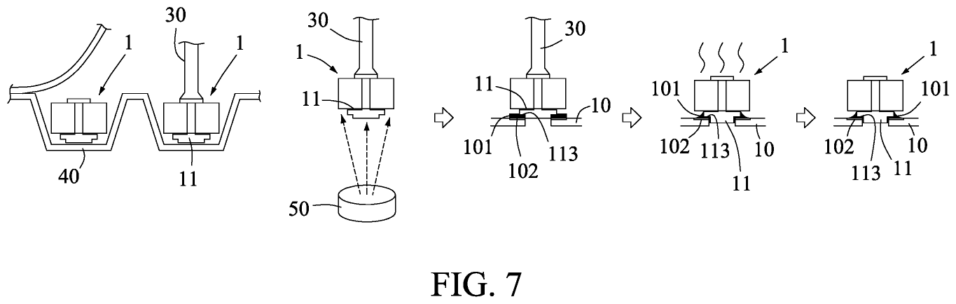

Referring to FIG. 7, in one embodiment of the present disclosure, a difference from the embodiments above is that, the fluid device 1 can be picked up by the tool 30, the fluid device 1 is moved by the tool 30 to an assembly position of the object 10 according to the comparison information of the comparison device 50, the fluid device 1 is pressed downward by the tool 30, and the fluid device 1 is released or loosened from the tool 30, for the assembly portion 11 to be placed at the assembly position of the object 10. Moreover, the weldable surface 113 and the tin layer 101 are heated, cooled and solidified so as to combine the object 10 and the assembly portion 11, allowing the fluid device 1 to be securely combined with the object 10 by using the assembly portion 11, thereby enabling the present disclosure to better meet actual assembly requirements.

In one embodiment of the present disclosure, when the fluid device 1 is moved by the tool 30 to the assembly position of the object 10, a contact of the fluid device 1 with the object 10 is sensed by the tool 30, and the fluid device 1 is released or loosened from the tool 30, for the assembly portion 11 to be placed at the assembly position of the object 10.

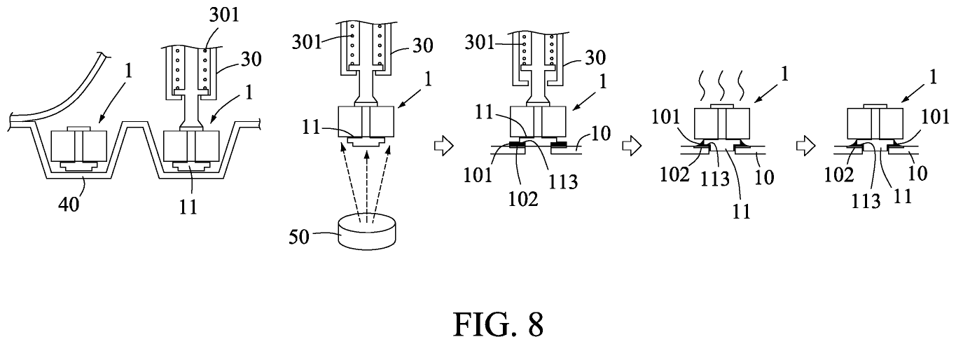

Referring to FIG. 8, in one embodiment of the present disclosure, a difference from the embodiments above is that, the fluid device 1 can be picked up by the tool 30, the fluid device 1 is moved by the tool 30 to an assembly position of the object 10 according to the comparison information of the comparison device 50, the fluid device 1 is elastically pressed downward by the tool 30 by using an elastic assembly 301, and the fluid device 1 is released or loosened from the tool 30, for the assembly portion 11 to be placed at the assembly position of the object 10. Moreover, the weldable surface 113 and the tin layer 101 are heated, cooled and solidified so as to combine the object 10 and the assembly portion 11, allowing the fluid device 1 to be securely combined with the object 10 by using the assembly portion 11, thereby enabling the present disclosure to better meet actual assembly requirements.

Referring to FIG. 9, in one embodiment of the present disclosure, a difference from the embodiments above is that, the block portion 12 can be shaped as a sheet, a fan or a blade, and the block portion 12 is formed as a movable or rotatable form, so as to use the block portion 12 for blocking or rotating to change a direction of a fluid, further guiding the fluid to a position at which a heat source is produced or a position requiring heat dissipation for heat dissipation by using the fluid, enabling the block portion 12 to achieve an effect of efficiently guiding or disturbing the fluid for heat dissipation.

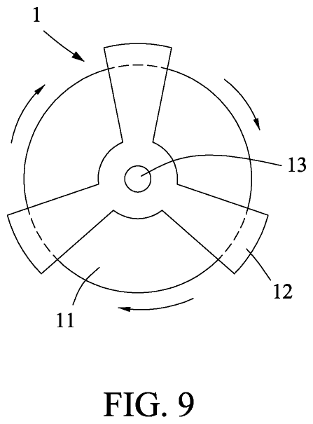

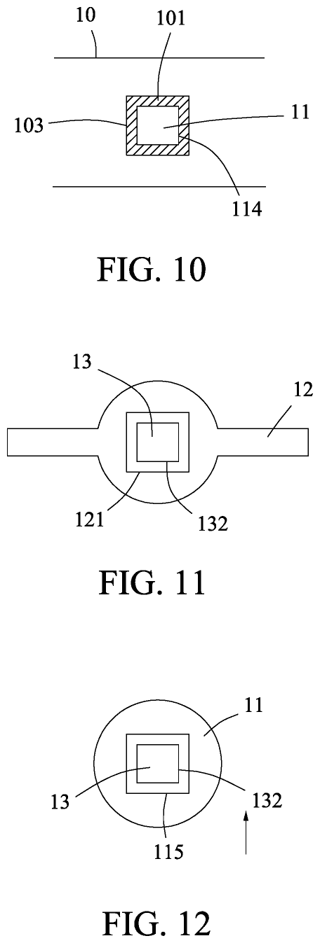

Referring to FIG. 10, in one embodiment of the present disclosure, a difference from the embodiments above is that, the assembly portion 11 is provided with a stop portion 114, the object 10 is provided with a corresponding stop portion 103, and the stop portion 114 of the assembly portion 11 and the corresponding stop portion 103 of the object 10 are correspondingly stopped. Or, a tin solder which is heated, cooled and solidified is provided between the stop portion 114 and the corresponding stop portion 103, allowing the fluid device 1 to be securely combined with the object 10 by using the assembly portion 11, thereby enabling the present disclosure to better meet actual assembly requirements.

Referring to FIG. 11, in one embodiment of the present disclosure, a difference from the embodiments above is that, the shaft 13 is provided with a stop portion 132, the block portion 12 is provided with a corresponding stop portion 121, and the stop portion 132 of the shaft 13 and the corresponding stop portion 121 of the block portion 12 are correspondingly stopped, for the block portion 12 to be securely combined at the shaft 13, thereby enabling the present disclosure to better meet actual assembly requirements.

Referring to FIG. 12, in one embodiment of the present disclosure, a difference from the embodiments above is that, the shaft 13 is provided with a stop portion 132, the assembly portion 11 is provided with a corresponding stop portion 115, and the stop portion 132 of the shaft 13 and the corresponding stop portion 115 of the assembly portion 11 are correspondingly stopped, for the assembly portion 11 to be securely combined at the shaft 13, thereby enabling the present disclosure to better meet actual assembly requirements.

In addition, the block portion 12 can also be provided with a stop portion, the assembly portion 11 is provided with a corresponding stop portion (not shown), and the stop portion and the corresponding stop portion are correspondingly stopped, for the assembly portion 11 to be securely combined with the block portion 12, thereby enabling the present disclosure to better meet actual assembly requirements.

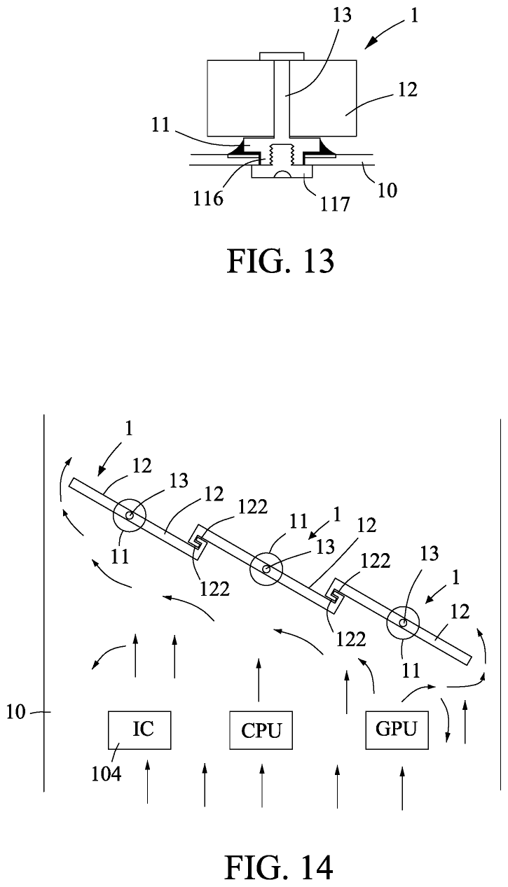

Referring to FIG. 13, in one embodiment of the present disclosure, a difference from the embodiments above is that, the assembly portion 11 includes an engaging portion 116, and the engaging portion 116 and a corresponding engaging portion 117 are engaged to clamp the object 10, allowing the fluid device 1 to be securely combined with the object 10 by using the engaging portion 116 and the corresponding engaging portion 117, thereby enabling the present disclosure to better meet actual assembly requirements.

Referring to FIG. 14, in one embodiment of the present disclosure, a difference from the above embodiments is that, the block portion 12 has a fastening portion 122, and one or more of the block portions 12 are engaged with each other by using the fastening portion 122 so as to increase an area of the block portion 12. Moreover, the object 10 has a fluid, and the block portion 12 can perform blocking or rotate to change the direction of the fluid, thereby enabling the block portion 12 to achieve an effect of efficiently guiding or disturbing the fluid for heat dissipation.

The object 10 is provided with a chip, a CPU, a GPU or a heat generating assembly 104, and the block portion 12 is disposed according to the position of the chip, the CPU, the GPU or the heat generating assembly 104 to guide a fluid for heat dissipation.

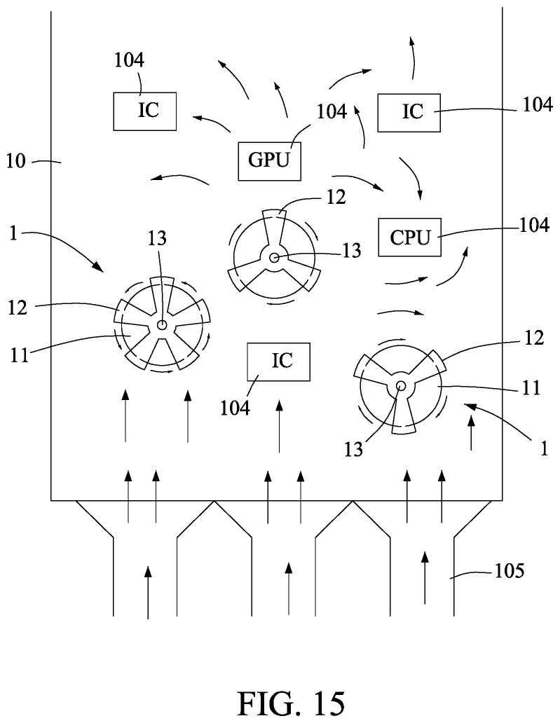

Referring to FIG. 15, in one embodiment of the present disclosure, a difference from the above embodiments is that, the object 10 includes an inlet portion 105 for a fluid to enter the object 10 to allow the fluid device 1 to come into contact with the fluid. Moreover, the block portion 12 is shaped as a fan, a blade or a sheet which is driven by the fluid to move, rotate or turn, allowing the block portion 12 to perform blocking or rotate to change a direction of the fluid, thereby enabling the block portion 12 to achieve an effect of efficiently guiding or disturbing the fluid for heat dissipation.

In one embodiment of the present disclosure, the fluid device 1 is installed at a local position of the object 10 (for example, a position through which a fluid passes) and is for generating guidance for a fluid at the installation position or near the installation position of the fluid device 1 to guide the fluid to the position of the heat generating assembly 104, for heat dissipation of the heat generating assembly 104.

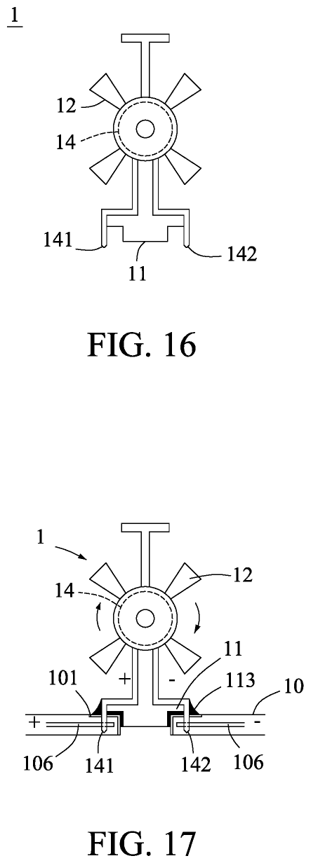

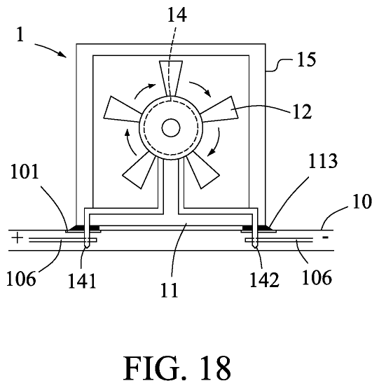

Referring to FIG. 16 to FIG. 18, in one embodiment of the present disclosure, a difference from the embodiments above is that, the fluid device 1 further includes an electric conductive portion 14 (for example, an electric motor) for conducting a current to electrically drive the block portion 12 to operate. In this embodiment, the electric conductive portion 14 can be disposed at the assembly portion 11, and the block portion 12 can be a blade and is disposed at the electric conductive portion 14. The electric conductive portion 14 includes a positive electrode 141 and a negative electrode 142, the object 10 can be a printed circuit board and includes a corresponding electric conductive portion 106, and the positive electrode 141 and the negative electrode 142 are connected to the corresponding electric conductive portion 106. Thus, when the object 10 operates in coordination with an electronic apparatus, with the coordination of the positive electrode 141 and the negative electrode 142 connected to the corresponding electric conductive portion 106, electric power needed for operating the electric conductive portion 14 is supplied.

During use, the fluid device 1 can be combined with the object 10 by using the assembly portion 11, and the weldable surface 113 and the tin layer 101 are heated, cooled and solidified so as to combine the object 10 and the assembly portion 11, allowing the fluid device 1 to be securely combined with the object 10 by using the assembly portion 11. Moreover, the block portion 12 is driven to rotate (or move) by the electric conductive portion 14, and a wind flow is generated by the electric conductive portion 14 in coordination with the block portion 12, so as to guide a fluid to a position at which a heat source is produced or a position needing heat dissipation and to use the fluid for heat dissipation, allowing the block portion 12 to achieve an effect of efficiently guiding or disturbing the fluid for heat dissipation.

In one embodiment of the present disclosure, the fluid device 1 further includes a hood 15. The hood 15 can cover, shield or protect the block portion 12 according to requirements, so as to guide the fluid to a position at which a heat source is produced or a position needing heat dissipation when the wind flow is produced by the block portion 12.

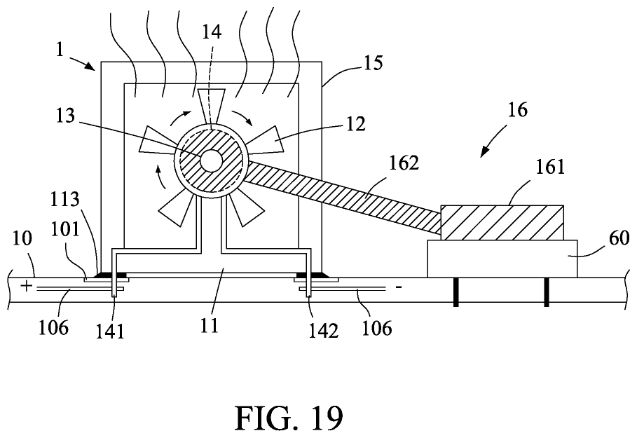

Refer FIG. 19 showing a fluid device of the present disclosure. The fluid device 1 includes an assembly portion 11, a block portion 12, a shaft 13 and a heat conduction module 16.

The assembly portion 11 is for assembling with an object 10.

The block portion 12 for guiding a fluid, which is a gas or a liquid.

The shaft 13 is combined with the block portion 12 and the block portion 12.

The heat conduction module 16 is connected to the block portion 12 or a heat generator 60, and is for conducting a heat source of the heat generator 60 to the block portion 12 for heat dissipation.

During use, the fluid device 1 can be combined with the object 10 by using the assembly portion 11, and the heat generator 60 can be disposed at the object 10, allowing the fluid device 1 to achieve an effect of being securely disposed at the object 10 by using the assembly portion 11. Moreover, by conducting the heat source of the heat generator 60 by the heat conduction module 16 to the block portion 12, since the shaft 13 configures the block portion 12 to be a movable type, the fluid is guided or disturbed by rotating of the block portion 12 when the heat source of the heat generator 60 is conducted by the heat conduction module 16 to the block portion 12 so as to use the fluid for heat dissipation, thereby enabling the block portion 12 to achieve an effect of efficiently guiding or disturbing the fluid for heat dissipation. In one embodiment of the present disclosure, the assembly portion 11 of the fluid device 1 and the object 10 can be directly combined, or the fluid device 1 can be welded and combined with the object 10 by using the weldable surface 113 of the assembly portion 11 and the tin layer 101 (or the copper layer 102) of the object 10.

In one embodiment of the present disclosure, the object 10 can be a printed circuit board, a water cooling apparatus, a gas cooling apparatus, a rack, a casing, a tray, a cage, a cupboard, a slide rail or a cabinet, thereby enabling the present disclosure to better meet actual application requirements.

In one embodiment of the present disclosure, the block portion 12 can be a vertical structure, and is shaped as a sheet, a fan or a blade, and the block portion 12 is rotated or turned to drive or control the fluid for heat dissipation.

In one embodiment of the present disclosure, the assembly portion 11 is provided with the electric conductive portion 14 (for example, an electric motor), or the assembly portion 11 is an electric conductive portion. The electric conductive portion 14 is for conducting a current to electrically drive the block portion 12 to operate. In this embodiment, the electric conductive portion 14 can be disposed at the assembly portion 11, and the block portion 12 can be a blade and is disposed at the electric conductive portion 14. The electric conductive portion 14 includes a positive electrode 141 and a negative electrode 142, the object 10 can be a printed circuit board and includes a corresponding electric conductive portion 106, and the positive electrode 141 and the negative electrode 142 are connected to the corresponding electric conductive portion 106. Thus, when the object 10 operates in coordination with an electronic apparatus, with the coordination of the positive electrode 141 and the negative electrode 142 connected to the corresponding electric conductive portion 106, electric power needed for operating the block portion 12 is supplied.

In one embodiment of the present disclosure, the heat conduction module 16 includes a heat conductor 161 and an intermediate heat conductor 162. The heat conductor 161 is a heat sink, and the heat generator 60 is a chip, a CPU, a GPU or a heat generating assembly. The heat conductor 161 is disposed at the heat generator 60. The intermediate heat conductor 162 is connected to the block portion 12 and the heat conductor 161. The heat conductor 161 is for guiding a heat source of the heat generator 60 to the intermediate heat conductor 162, and the intermediate heat conductor 162 is for guiding the heat source to the block portion 12. The fluid is guided or disturbed by rotating of the block portion 12 so as to use the fluid for heat dissipation, thereby enabling the block portion 12 to achieve an effect of efficiently guiding or disturbing the fluid for heat dissipation.

In one embodiment of the present disclosure, the assembly portion 11, the positive electrode 141 or the negative electrode 142 is a protruding plug, a solder paste, a solder ball, a tin block, a sheet, a cylinder or a recessed body, thereby enabling the present disclosure to better meet actual assembly requirements.

In one embodiment of the present disclosure, the assembly portion 11, the positive electrode 141 or the negative electrode 142 is welded with the tin layer 101 (or the copper layer 102) of the object 10 (or a printed circuit board), enabling the assembly portion 11, the positive electrode 141 and the negative electrode 142 to achieve an effect of being securely disposed at the object 10.

In one embodiment of the present disclosure, the fluid device 1 further includes a hood 15. The hood 15 covers, shields or protects the block portion 12. The hood 15 can cover, shield or protect the block portion 12 according to requirements, so as to guide the fluid by the hood 15 to a position at which a heat source is produced or a position needing heat dissipation when the wind flow is produced by the block portion 12.

In one embodiment of the present disclosure, the assembly portion 11 (or the fluid device 1 or the heat conduction module 16) and the heat conduction module 16 are respectively welded or bonded at the object 10 and the heat generator 60, and a descending, sinking or downward force or a pull force is produced by heat welding performed so as to cool the solder from a liquid state to a solid state, or a descending, sinking or downward force or a pull force is produced by bonding, for the assembly portion 11 (or the fluid device 1) and the heat conduction module 16 to respectively adhere, lean against or get close to the object 10 and the heat generator 60.

In one embodiment of the present disclosure, a solder paste, a solder ball or an adhesive become a liquid state or a soft body due to heating when welding or bonding is performed, and is then cooled to again become a solid state or a hard body, wherein the solder paste, the solder ball or the adhesive can be disposed at the fluid device 1, the assembly portion 11, the heat conduction module 16, the object 10 or the heat generator 60.

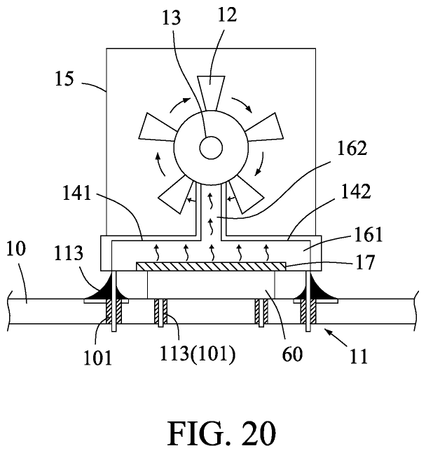

As shown in FIG. 20, in one embodiment of the present disclosure, a difference from the embodiments above is that, an intermediate heat sink 17 is provided between the heat conductor 161 and the heat generator 60, wherein the intermediate heat sink 17 is a thermal paste, a thermal pad or a thermal elastic body.

During use, the intermediate heat sink 17 is used to conduct the heat source of the heat generator 60 to the heat conductor 161, and the heat conductor 161 then guides the heat source to the intermediate heat conductor 162, for the intermediate heat conductor 162 to guide the source to the block portion 12. The fluid is guided or disturbed by rotating of the block portion 12 so as to use the fluid for heat dissipation, thereby enabling the block portion 12 to achieve an effect of efficiently guiding or disturbing the fluid for heat dissipation.

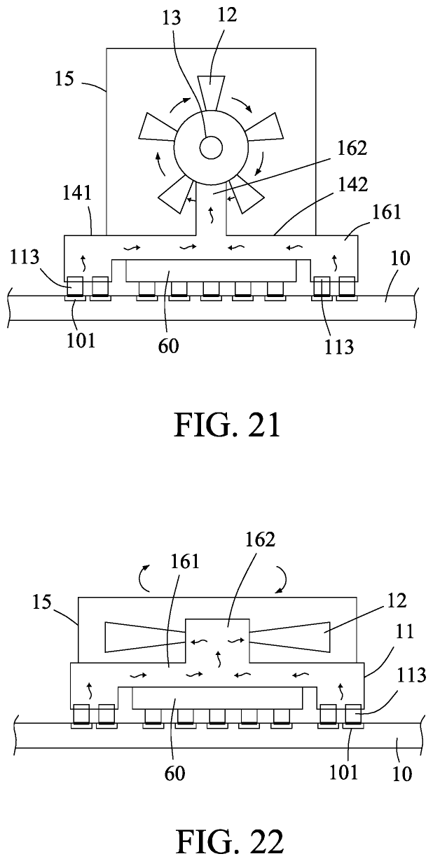

Referring to FIG. 21, in one embodiment of the present disclosure, a difference from the embodiments above is that, the assembly portion 11 (or the heat conduction module 16) includes a weldable surface 113 (for example, a solder paste or a solder ball), and the object 10 includes a tin layer 101 (or a copper layer 102), for the assembly portion 11 to be welded at the tin layer 101 (or the copper layer 102) of the object 10 by using the weldable surface 113. The weldable surface 113 and the tin layer 101 (or the copper layer 102) become a liquid state due to heat welding, and are then cooled to again become a solid state, and a descending, sinking or downward force or a pull force is produced by the welding. Thus, in addition to allowing the fluid device 1 to be securely disposed at the object 10 by using the assembly portion 11, the heat conduction module 16 can be adhered to the heat generator 60 to promote conduction of the heat source.

In one embodiment of the present disclosure, the assembly portion 11 (or the fluid device 1 or the heat conduction module 16) can be adhered to the object 10, an adhesive disposed at the assembly portion 11 and the object 10 during adhesion becomes a liquid state or a soft body due to heating, and is cooled to again become a solid state or a hard body, and a descending, sinking or downward force or a pull force is produced by the adhesion, for the heat conduction module 16 to adhere, lean against or get close to the heat generator 60 or the object 10.

Referring to FIG. 22, in one embodiment of the present disclosure, a difference from the embodiments above is that, apart from configuring the fluid device 1 as the vertical form as in the embodiments above, the fluid device 1 can further be configured to a horizontal form of this embodiment, thereby enabling the present disclosure to better meet actual application requirements.

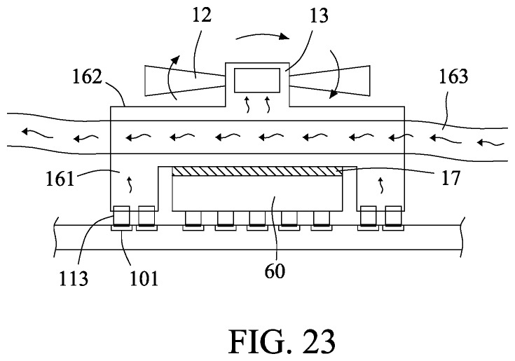

Referring to FIG. 23, in one embodiment of the present disclosure, a difference from the embodiments above is that, the heat conductor 161 of the heat conduction module 16 includes a channel portion 163 which is for a fluid to pass through for heat dissipation, or the channel portion 163 can be for a gaseous fluid (or a liquid fluid) to pass through for heat dissipation.

During use, the intermediate heat sink 17 is used to conduct the heat source of the heat generator 60 to the heat conductor 161, and the heat conductor 161 can first dissipate heat for the heat source by using the liquid fluid or the gaseous fluid in the channel portion 163 and then guide the remaining heat source by the heat conductor 161 to the intermediate heat conductor 162, for the intermediate heat conductor 162 to guide the heat source to the block portion 12. The fluid is guided or disturbed by rotating of the block portion 12 so as to use the fluid for heat dissipation, thereby enabling the block portion 12 to achieve an effect of efficiently guiding or disturbing the fluid for heat dissipation.

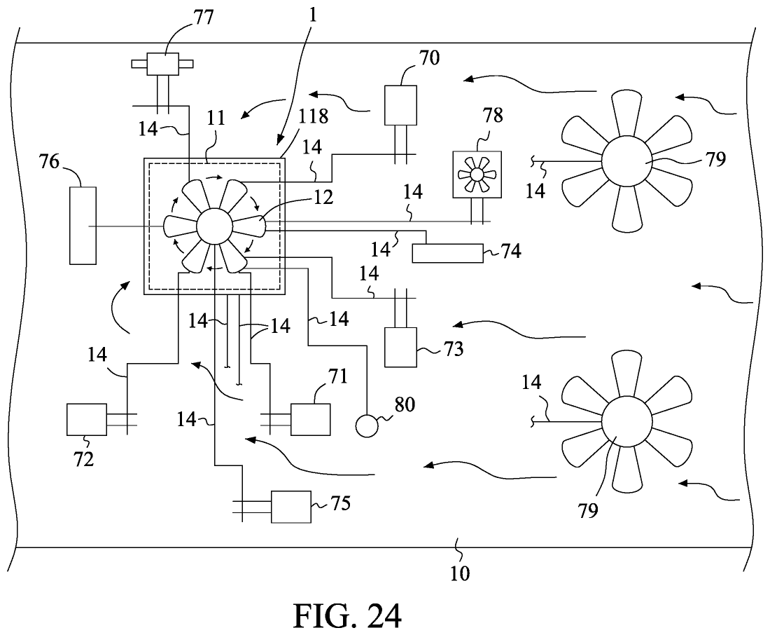

Referring to FIG. 24, in one embodiment of the present disclosure, a difference from the above embodiments is that, the fluid device 1 includes an assembly portion 11 and a block portion 12. The assembly portion 11 is for assembling with an object 10. The block portion 12 is disposed at the assembly portion 11 and is for blocking or guiding a fluid. The fluid device 1 further includes an electric conductive portion 14 (for example, an electric motor) for conducting electric power generated by a motion of the block portion 12 of the fluid device 1 to power another conductive object, or for storing the electric power in a power storage or a battery.

In one embodiment of the present disclosure, a difference from the embodiments above is that, the fluid device 1 further includes a body 118, and the assembly portion 11 is disposed at the body 118. Thus, the body 118 can be disposed at the object 10 (for example, a circuit board) by using the assembly portion 11, further allowing the fluid device 1 to be securely assembled with the object 10, thereby enabling the present disclosure to better meet actual application requirements.

In one embodiment of the present disclosure, a difference from the embodiments above is that, in an actual application, the electric conductive portion 14 (for example, a power generator) can guide required electric power to a light emitter, a light emitting diode 70, a chip 71, a passive component 72 (or a battery), an active component 73 (or a power storage), an optical assembly 74, a switch 75, a memory 76, a motor 77, a fan 78, a heat sink 79, a circuit board 80, a transistor, a power supply device, a wire, a circuit, a fastener, a lock, a handle or a power generator. Thus, electric power generated by the electric conductive portion 14 driven by a motion of the block portion 12 of the fluid device 1 can be used to power another conductive object. Meanwhile, the fluid is guided or disturbed by rotating of the block portion 12 of the fluid device 1, so as to use the liquid to dissipate heat of the light emitter, the light emitting diode 70, the chip 71, the passive component 72 (or the battery), the active component 73 (or the power storage), the optical component 74, the switch 75, the memory 76, the motor 77, the fan 78, the heat sink 79, the circuit board 80, the transistor, the power supply device, the wire, the circuit, the fastener, the lock, the handle or the heat generator, thereby achieving an effect of efficiently guiding or disturbing the fluid for heat dissipation.

In conclusion, the fluid device of the present disclosure can provide a secure configuration and an effect of efficiently guiding or disturbing a fluid for heat dissipation.

It should be noted that the embodiments of the present invention are described above for illustration purposes and are not to be construed as limitations to the scope of the claims of the present invention.

What is claimed is:

1. A fluid device, comprising:
a block portion, for blocking or guiding a fluid;
wherein the fluid device further comprises an electric conductive portion for conducting electric power generated by a motion of the fluid device to power another conductive object or for storing the electric power in a power storage or a battery.

2. A fluid device, comprising:
a block portion, for blocking or guiding a fluid; and
a shaft, combined with the block portion;
wherein the fluid device further comprises an electric conductive portion for conducting electric power generated by a motion of the fluid device to power another conductive object or for storing the electric power in a power storage or a battery.

3. A fluid device, comprising:
an assembly portion, for assembling with an object; and
a block portion, disposed at the assembly portion, the block portion for blocking or guiding a fluid;
wherein the fluid device further comprises an electric conductive portion for conducting electric power generated by a motion of the fluid device to power another conductive object or for storing the electric power in a power storage or a battery.

4. A fluid device, comprising:
an assembly portion, for assembling with an object;
a block portion, for blocking or guiding a fluid; and
a shaft, combined with the block portion;
wherein the fluid device further comprises an electric conductive portion for conducting electric power generated by a motion of the fluid device to power another conductive object or for storing the electric power in a power storage or a battery.

5. The fluid device according to claim 1, wherein the assembly portion or one end or both ends of the shaft of the fluid device are provided with a stop portion, or the stop portion stops against the block portion or the assembly portion, or the assembly portion or the shaft of the fluid device is provided with a stop portion, or the block portion is provided with a corresponding stop portion, or the stop portion and the corresponding stop portion are correspondingly stopped, or the assembly portion of the fluid device is provided with a stop portion, or the object is provided with a corresponding stop portion, or the stop portion and the corresponding stop portion are correspondingly stopped, or the block portion is provided with a stop portion, or the assembly portion of the fluid device is provided with a corresponding stop portion, or the stop portion and the corresponding stop portion are correspondingly stopped.

6. The fluid device according to claim 2, wherein the assembly portion or one end or both ends of the shaft of the fluid device are provided with a stop portion, or the stop portion stops against the block portion or the assembly portion, or the assembly portion or the shaft of the fluid device is provided with a stop portion, or the block portion is provided with a corresponding stop portion, or the stop portion and the corresponding stop portion are correspondingly stopped, or the assembly portion of the fluid device is provided with a stop portion, or the object is provided with a corresponding stop portion, or the stop portion and the corresponding stop portion are correspondingly stopped, or the block portion is provided with a stop portion, or the assembly portion of the fluid device is provided with a corresponding stop portion, or the stop portion and the corresponding stop portion are correspondingly stopped.

7. The fluid device according to claim 3, wherein the assembly portion or one end or both ends of the shaft of the fluid device are provided with a stop portion, or the stop portion stops against the block portion or the assembly portion, or the assembly portion or the shaft of the fluid device is provided with a stop portion, or the block portion is provided with a corresponding stop portion, or the stop portion and the corresponding stop portion are correspondingly stopped, or the assembly portion of the fluid device is provided with a stop portion, or the object is provided with a corresponding stop portion, or the stop portion and the corresponding stop portion are correspondingly stopped, or the block portion is provided with a stop portion, or the assembly portion of the fluid device is provided with a corresponding stop portion, or the stop portion and the corresponding stop portion are correspondingly stopped.

8. The fluid device according to claim 4, wherein the assembly portion or one end or both ends of the shaft of the fluid device are provided with a stop portion, or the stop portion stops against the block portion or the assembly portion, or the assembly portion or the shaft of the fluid device is provided with a stop portion, or the block portion is provided with a corresponding stop portion, or the stop portion and the corresponding stop portion are correspondingly stopped, or the assembly portion of the fluid device is provided with a stop portion, or the object is provided with a corresponding stop portion, or the stop portion and the corresponding stop portion are correspondingly stopped, or the block portion is provided with a stop portion, or the assembly portion of the fluid device is provided with a corresponding stop portion, or the stop portion and the corresponding stop portion are correspondingly stopped.

9. The fluid device according to claim 1, wherein the fluid device is picked up by a tool, and the fluid device is moved by the tool to an assembly position of the object, or the fluid device is moved by the tool to a default height of an assembly position of the object, or the fluid device is pressed downward or elastically pressed downward by the tool, or a contact of the device with the object is sensed by the tool, or the fluid device is released or loosened from the tool, or the assembly portion of the fluid device is placed at an assembly position of the object.

10. The fluid device according to claim 2, wherein the fluid device is picked up by a tool, and the fluid device is moved by the tool to an assembly position of the object, or the fluid device is moved by the tool to a default height of an assembly position of the object, or the fluid device is pressed downward or elastically pressed downward by the tool, or a contact of the device with the object is sensed by the tool, or the fluid device is released or loosened from the tool, or the assembly portion of the fluid device is placed at an assembly position of the object.

11. The fluid device according to claim 3, wherein the fluid device is picked up by a tool, and the fluid device is moved by the tool to an assembly position of the object, or the fluid device is moved by the tool to a default height of an assembly position of the object, or the fluid device is pressed downward or elastically pressed downward by the tool, or a contact of the device with the object is sensed by the tool, or the fluid device is released or loosened from the tool, or the assembly portion of the fluid device is placed at an assembly position of the object.

12. The fluid device according to claim 4, wherein the fluid device is picked up by a tool, and the fluid device is moved by the tool to an assembly position of the object, or the fluid device is moved by the tool to a default height of an assembly position of the object, or the fluid device is pressed downward or elastically pressed downward by the tool, or a contact of the device with the object is sensed by the tool, or the fluid device is released or loosened from the tool, or the assembly portion of the fluid device is placed at an assembly position of the object.

13. The fluid device according to claim 1, wherein the block portion has a fastening portion, more than one block portion is fastened with another via the fastening portion to increase an area of the block portion, or the block portion is shaped as a sheet, a fan or a blade, or the block portion is movable or rotatable, or the block portion is at a fixed position, or the block portion is for being installed at a position of the object through which a fluid passes or for guiding or dissipating heat of a fluid at an installation position or near an installation position.

14. The fluid device according to claim 2, wherein the block portion has a fastening portion, more than one block portion is fastened with another via the fastening portion to increase an area of the block portion, or the block portion is shaped as a sheet, a fan or a blade, or the block portion is movable or rotatable, or the block portion is at a fixed position, or the block portion is for being installed at a position of the object through which a fluid passes or for guiding or dissipating heat of a fluid at an installation position or near an installation position.

15. The fluid device according to claim 3, wherein the block portion has a fastening portion, more than one block portion is fastened with another via the fastening portion to increase an area of the block portion, or the block portion is shaped as a sheet, a fan or a blade, or the block portion is movable or rotatable, or the block portion is at a fixed position, or the block portion is for being installed at a position of the object through which a fluid passes or for guiding or dissipating heat of a fluid at an installation position or near an installation position.

16. The fluid device according to claim 4, wherein the block portion has a fastening portion, more than one block portion is fastened with another via the fastening portion to increase an area of the block portion, or the block portion is shaped as a sheet, a fan or a blade, or the block portion is movable or rotatable, or the block portion is at a fixed position, or the block portion is for being installed at a position of the object through which a fluid passes or for guiding or dissipating heat of a fluid at an installation position or near an installation position.

17. The fluid device according to claim 1, wherein the fluid device is assembled at an object which has a fluid, or the block portion can block or rotate to change a direction of the fluid, or the object has an inlet portion, or the inlet portion is for the fluid to enter the object to enable the fluid device to come into contact with the fluid.

18. The fluid device according to claim 2, wherein the fluid device is assembled at an object which has a fluid, or the block portion can block or rotate to change a direction of the fluid, or the object has an inlet portion, or the inlet portion is for the fluid to enter the object to enable the fluid device to come into contact with the fluid.

19. The fluid device according to claim 3, wherein the fluid device is assembled at an object which has a fluid, or the block portion can block or rotate to change a direction of the fluid, or the object has an inlet portion, or the inlet portion is for the fluid to enter the object to enable the fluid device to come into contact with the fluid.

20. The fluid device according to claim 4, wherein the fluid device is assembled at an object which has a fluid, or the block portion can block or rotate to change a direction of the fluid, or the object has an inlet portion, or the inlet portion is for the fluid to enter the object to enable the fluid device to come into contact with the fluid.

21. The fluid device according to claim 1, wherein the electric conductive portion has a positive electrode and a negative electrode, the object has a corresponding electric conductive portion, and the positive electrode and the negative electrode are connected to the corresponding electric conductive portion.

22. The fluid device according to claim 2, wherein the electric conductive portion has a positive electrode and a negative electrode, the object has a corresponding electric conductive portion, and the positive electrode and the negative electrode are connected to the corresponding electric conductive portion.

23. The fluid device according to claim 3, wherein the electric conductive portion has a positive electrode and a negative electrode, the object has a corresponding electric conductive portion, and the positive electrode and the negative electrode are connected to the corresponding electric conductive portion.

24. The fluid device according to claim 4, wherein the electric conductive portion has a positive electrode and a negative electrode, the object has a corresponding electric conductive portion, and the positive electrode and the negative electrode are connected to the corresponding electric conductive portion.

25. The fluid device according to claim 1, further comprising a heat conduction module connected to the block portion or a heat generator, wherein the heat conduction module is for conducting a heat source of the heat generator to the block portion for heat dissipation, or the heat conduction module comprises a heat conductor or an intermediate heat conductor, the heat conductor is disposed at the heat generator, and the intermediate heat conductor is connected to the block portion or the heat conductor, or the heat conductor is for guiding a heat source of the heat generator to the intermediate heat conductor, or the intermediate heat conductor is for guiding the heat source to the block portion for heat dissipation, or the heat conduction module or a heat conductor of the heat conduction module comprises a channel portion, and the channel portion is for a fluid to pass through for heat dissipation, or the channel portion is for a liquid fluid or a gaseous fluid to pass through for heat dissipation.

26. The fluid device according to claim 2, further comprising a heat conduction module connected to the block portion or a heat generator, wherein the heat conduction module is for conducting a heat source of the heat generator to the block portion for heat dissipation, or the heat conduction module comprises a heat conductor or an intermediate heat conductor, the heat conductor is disposed at the heat generator, and the intermediate heat conductor is connected to the block portion or the heat conductor, or the heat conductor is for guiding a heat source of the heat generator to the intermediate heat conductor, or the intermediate heat conductor is for guiding the heat source to the block portion for heat dissipation, or the heat conduction module or a heat conductor of the heat conduction module comprises a channel portion, and the channel portion is for a fluid to pass through for heat dissipation, or the channel portion is for a liquid fluid or a gaseous fluid to pass through for heat dissipation.

27. The fluid device according to claim 3, further comprising a heat conduction module connected to the block portion or a heat generator, wherein the heat conduction module is for conducting a heat source of the heat generator to the block portion for heat dissipation, or the heat conduction module comprises a heat conductor or an intermediate heat conductor, the heat conductor is disposed at the heat generator, and the intermediate heat conductor is connected to the block portion or the heat conductor, or the heat conductor is for guiding a heat source of the heat generator to the intermediate heat conductor, or the intermediate heat conductor is for guiding the heat source to the block portion for heat dissipation, or the heat conduction module or a heat conductor of the heat conduction module comprises a channel portion, and the channel portion is for a fluid to pass through for heat dissipation, or the channel portion is for a liquid fluid or a gaseous fluid to pass through for heat dissipation.

28. The fluid device according to claim 4, further comprising a heat conduction module connected to the block portion or a heat generator, wherein the heat conduction module is for conducting a heat source of the heat generator to the block portion for heat dissipation, or the heat conduction module comprises a heat conductor or an intermediate heat conductor, the heat conductor is disposed at the heat generator, and the intermediate heat conductor is connected to the block portion or the heat conductor, or the heat conductor is for guiding a heat source of the heat generator to the intermediate heat conductor, or the intermediate heat conductor is for guiding the heat source to the block portion for heat dissipation, or the heat conduction module or a heat conductor of the heat conduction module comprises a channel portion, and the channel portion is for a fluid to pass through for heat dissipation, or the channel portion is for a liquid fluid or a gaseous fluid to pass through for heat dissipation.

29. The fluid device according to claim 1, further comprising a body, or wherein the body has an assembly portion.

30. The fluid device according to claim 2, further comprising a body, or wherein the body has an assembly portion.

31. The fluid device according to claim 3, further comprising a body, or wherein the body has an assembly portion.

32. The fluid device according to claim 4, further comprising a body, or wherein the body has an assembly portion.
